(19) United States
(12) Patent Application Publication
(10) Pub. No.: US 2008/0247217 A1
(43) Pub. Date: Oct. 9, 2008

(54) Integrated circuit, memory cell array, memory module, method of operating an integrated circuit, and computing system

(76) Inventor: Bernhard Ruf, Sauerlach (DE)

Correspondence Address: SLATER & MATSIL LLP, 17950 PRESTON ROAD, SUITE 1000, DALLAS, TX, 75252, US

(21) Appl. No.: 11/732,696

(22) Filed: Apr. 4, 2007

(51) Int. Cl. G11C 11/00

(52) U.S. Cl. 365/148

(57) ABSTRACT

An integrated circuit includes a plurality of resistivity changing memory cells and a plurality of resistivity changing reference cells. The integrated circuit is arranged such that each memory cell is switchable between N resistance levels, N being an integer greater than or equal to 2. To each of at least two possible resistance levels of a memory cell an individual reference cell as assigned. A resistance level of a memory cell is determined or set depending on the resistance level of the reference cell which is assigned to the resistance level of the memory cell.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a cross-sectional view of a solid electrolyte memory cell set to a first switching state;

FIG. 1B shows a cross-sectional view of a solid electrolyte memory cell set to a second memory state;

FIG. 2A shows a schematic drawing of an integrated circuit according to one embodiment of the present invention;

FIG. 2B shows a schematic drawing of an integrated circuit according to one embodiment of the present invention;

FIG. 3 shows a method of operating an integrated circuit according to one embodiment of the present invention;

FIG. 4 shows a method of operating an integrated circuit according to one embodiment of the present invention;

FIG. 5 shows a schematic diagram illustrating the development of different resistance levels of a memory cell over time;

FIG. 6 shows a method of operating an integrated circuit according to one embodiment of the present invention;

FIG. 7 shows a method of operating an integrated circuit according to one embodiment of the present invention;

FIG. 8 shows a diagram illustrating the development of different resistance levels of a memory cell over time;

FIG. 9A shows a memory module according to one embodiment of the present invention;

FIG. 9B shows a stacked memory module according to one embodiment of the present invention;

FIG. 10 shows a computing system according to one embodiment of the present invention;

FIG. 11 shows a cross-sectional view of a phase changing memory cell;

FIG. 12 shows a schematic drawing of a memory device including resistivity changing memory cells;

FIG. 13A shows a cross-sectional view of a carbon memory cell set to a first switching state;

FIG. 13B shows a cross-sectional view of a carbon memory cell set to a second switching state;

FIG. 14A shows a schematic drawing of a resistivity changing memory cell; and

FIG. 14B shows a schematic drawing of a resistivity changing memory cell.

### DETAILED DESCRIPTION OF ILLUSTRATIVE EMBODIMENTS

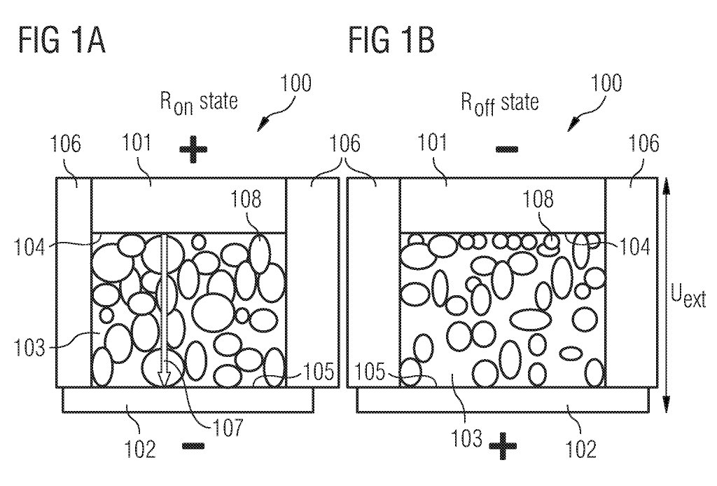

Since the embodiments of the present invention can be applied to solid electrolyte devices like CBRAM (conductive bridging random access memory) devices, in the following description, making reference to FIGS. 1A and 1B, a basic principle underlying embodiments of CBRAM devices will be explained.

As shown in FIG. 1A, a CBRAM cell 100 includes a first electrode 101 a second electrode 102, and a solid electrolyte block (in the following also referred to as ion conductor block) 103 which includes the active material and which is sandwiched between the first electrode 101 and the second electrode 102. This solid electrolyte block 103 can also be shared between a large number of memory cells (not shown here). The first electrode 101 contacts a first surface 104 of the ion conductor block 103, the second electrode 102 contacts a second surface 105 of the ion conductor block 103. The ion conductor block 103 is isolated against its environment by an isolation structure 106. The first surface 104 usually is the top surface, the second surface 105 the bottom surface of the ion conductor 103. In the same way, the first electrode 101 generally is the top electrode, and the second electrode 102 the bottom electrode of the CBRAM cell. One of the first electrode 101 and the second electrode 102 is a reactive electrode, the other one an inert electrode. Here, the first electrode 101 is the reactive electrode, and the second electrode 102 is the inert electrode. In this example, the first electrode 101 includes silver (Ag), the ion conductor block 103 includes silver-doped chalcogenide material, the second electrode 102 includes tungsten (W), and the isolation structure 106 includes SiO₂. The present invention is however not restricted to these materials. For example, the first electrode 101 may alternatively or additionally include copper (Cu) or zink (Zn), and the ion conductor block 103 may alternatively or additionally include copper-doped chalcogenide material. Further, the second electrode 102 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned compounds, and can also include alloys of the aforementioned metals or materials. The thickness of the ion conductor 103 may for example range between 5 nm and 500 nm. The thickness of the first electrode 101 may for example range between 10 nm and 100 nm. The thickness of the second electrode 102 may for example range between 5 nm and 500 nm, between 15 nm to 150 nm, or between 25 nm and 100 nm. It is to be understood that the present invention is not restricted to the above-mentioned materials and thicknesses.

In the context of this description, chalcogenide material (ion conductor) is to be understood for example as any compound containing oxygen, sulphur, selenium, germanium and/or tellurium. In accordance with one embodiment of the invention, the ion conducting material is, for example, a compound, which is made of a chalcogenide and at least one metal of the group I or group II of the periodic system, for example arsenic-trisulfide-silver. Alternatively, the chalcogenide material contains germanium-sulfide (GeSₓ), germanium-selenide (GeSeₓ), tungsten oxide (WOₓ), copper sulfide (CuSₓ) or the like. The ion conducting material may be a solid state electrolyte. Furthermore, the ion conducting material can be made of a chalcogenide material containing metal ions, wherein the metal ions can be made of a metal, which is selected from a group consisting of silver, copper and zinc or of a combination or an alloy of these metals.

If a voltage as indicated in FIG. 1A is applied across the ion conductor block 103, a redox reaction is initiated which drives Ag⁺ ions out of the first electrode 101 into the ion conductor block 103 where they are reduced to Ag, thereby forming Ag rich clusters 108 within the ion conductor block 103. If the voltage applied across the ion conductor block 103 is applied for an enhanced period of time, the size and the number of Ag rich clusters 108 within the ion conductor block 103 is increased to such an extent that a conductive bridge 107 between the first electrode 101 and the second electrode 102 is formed. In case that a voltage is applied across the ion conductor 103 as shown in FIG. 1B (inverse voltage compared to the voltage applied in FIG. 1A), a redox reaction is initiated which drives Ag⁺ ions out of the ion conductor block 103 into the first electrode 101 where they are reduced to Ag. As a consequence, the size and the number of Ag rich clusters within the ion conductor block 103 is reduced, thereby erasing the conductive bridge 107.

In order to determine the current memory status of a CBRAM cell, for example, a sensing current is routed through the CBRAM cell. The sensing current experiences a high resistance in case no conductive bridge 107 exists within the CBRAM cell, and experiences a low resistance in case a conductive bridge 107 exists within the CBRAM cell. A high resistance may for example represent “0”, whereas a low resistance represents “1”, or vice versa. The memory status detection may also be carried out using sensing voltages.

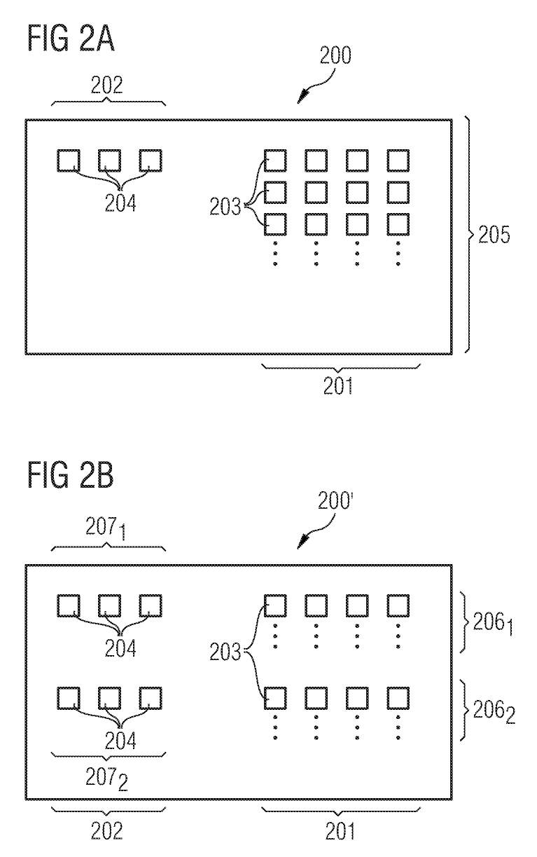

FIG. 2A shows an integrated circuit 200 according to one embodiment of the present invention. The integrated circuit 200 includes a memory cell area 201 and a reference cell area 202. The memory cell area 201 includes a plurality of resistivity changing memory cells 203. The reference cell area 202 includes a plurality of resistivity changing reference cells 204. The integrated circuit 200 is arranged such that each memory cell 203 is switchable between N resistance levels, N being an integer greater than or equal to 2, wherein to each of at least two possible resistance levels of a memory cell 203 an individual reference cell 204 is assigned. Each particular resistance level of a memory cell 203 is determined or set in dependence on the resistance level of the reference cell 204 which is assigned to the particular resistance level of the memory cell 203. For example, each memory cell 203 may adopt three different resistance values, wherein each resistance value of a memory cell 203 represents a memory state of the memory cell 203. In this case, at least three reference cells 204 are necessary, wherein a first reference cell 204 is assigned to all first memory states of the memory cells 203, a second reference cell 204 is assigned to all second memory states of the memory cells 203, and a third reference cell 204 is assigned to all third memory states of the memory cells 203 (it is assumed here that the resistance value of a particular resistance level is the same for all memory cells 203).

The provision of reference cells 204, inter alia, ensures that different resistance levels of a memory cell 203 can be distinguished from each other after a long period of time, due to the reference cells 204, resistance level drifting effects over long periods of time can be “compensated”. According to one embodiment of the present invention, the term “long periods of time” may for example mean a period of time ranging between 10 seconds and 10 years.

According to one embodiment of the present invention, an individual reference cell 204 is assigned to each possible resistance level of a memory cell 203. However, it may also be sufficient to assign reference cells 204 not to all resistance levels, but only to some resistance levels of the memory cells 203. By way of example, the resistance levels of the memory cells 203 may be split into a first resistance level group and a second resistance level group, wherein the resistance levels of the first resistance level group are easier to distinguish from other resistance levels than the resistance levels of the second resistance level group. Reference cells 204 are only assigned to resistance levels belonging to the second resistance level group. Reference cells 204 are only assigned to a particular resistance level if the difference between the particular resistance level and a neighboring resistance level falls below a predetermined threshold value. In other words: reference cells 204 are only assigned to resistance levels which are difficult to determine, compared to other resistance levels. In this way, the number of reference cells 204 can be reduced.

In the embodiment shown in FIG. 2A, the memory cells 203 form a memory cell array 205, wherein all memory cells 203 of the memory cell array 205 share the same N reference cells 204. Alternatively, in the embodiment shown in FIG. 2B, N reference cells 204 are assigned to each memory cell block 206 of the memory cell array, wherein the N reference cells 204 which are assigned to a memory cell block 206 are shared by the memory cells 203 of the memory cell block 206. Here, a first group 207, of reference cells 204 are shared by the memory cells 203 of a first block 206, of memory cells 203, and a second group 2072 of reference cells 204 are shared by the memory cells 203 of a second block 2062 of memory cells 203. This principle may be applied to an arbitrary number of memory cell blocks 206. Further, this principle may also be applied to memory cell banks or any other subunit of memory cells of the memory cell array 205. For example, N individual reference cells 204 may be assigned to each memory cell bank (not shown) of the memory cell array 205, wherein the N reference cells 204 which are assigned to a memory cell bank are shared by the memory cells 203 of the memory cell bank.

In the embodiments described above, N reference cells 204 are assigned to each memory cell array unit (memory cell block, memory cell bank, etc.). Assuming that the number of possible resistance levels is N, this means that, within a memory cell array unit, each resistance level is “represented” by one reference cell 204. However, it is also possible that one reference cell 204 simultaneously represents a resistance level of memory cells belonging to different memory cell array units. For example, only one reference cell 204 may be assigned to the highest resistance level of all memory cells 203 of the memory cell array 205, whereas for another resistance level, different reference cells 204 are assigned to different memory cell array units.

According to one embodiment of the invention, the density of the reference cells 204 is one set of reference cells per memory cell array (minimum density) up to one set of reference cells per byte (maximum density). The term “set of reference cells” in this context means a group of reference cells, the number of which being equal to the number of possible memory states, wherein each possible memory state is represented by one individual reference cell of the group of reference cells.

According to one embodiment of the invention, the whole integrated circuit 200 is a cell array including a plurality of resistivity changing memory cells 203 and a plurality of resistivity changing reference cells 204.

According to one embodiment of the invention, an integrated circuit is provided having a plurality of resistivity changing memory means and a plurality of resistivity changing reference means. Each memory means is switchable between N resistance levels, N being an integer greater than or equal to 2. To each of at least two possible resistance levels of a memory means an individual reference means is assigned. A particular resistance level of a memory means is determined in dependence of the resistance level of the reference means which is assigned to the particular resistance level of the memory means.

According to one embodiment of the invention, the resistivity changing memory means are resistivity changing memory cells, and the resistivity changing reference means are resistivity changing reference cells.

According to one embodiment of the invention, the resistivity changing memory cells may for example be programmable metallization cells (PMC), e.g., solid electrolyte memory cells, also known as conductive bridging memory cells (e.g., CBRAM cells=conductive bridging random access memory cells), magneto resistive memory cells (e.g., MRAM cells=magneto-resistive random access memory cells), phase changing memory cells (e.g. PCRAM cells=phase changing random access memory cells), organic memory cells (e.g., ORAM cells=organic random access memory cells), and the like.

According to one embodiment of the invention, the architecture of the reference cells 104 is identical to the architecture of the memory cells 203.

According to one embodiment of the invention, a memory module is provided having at least one integrated circuit or at least one memory cell array according to an embodiment of the invention. According to one embodiment of the invention, the memory module is stackable.

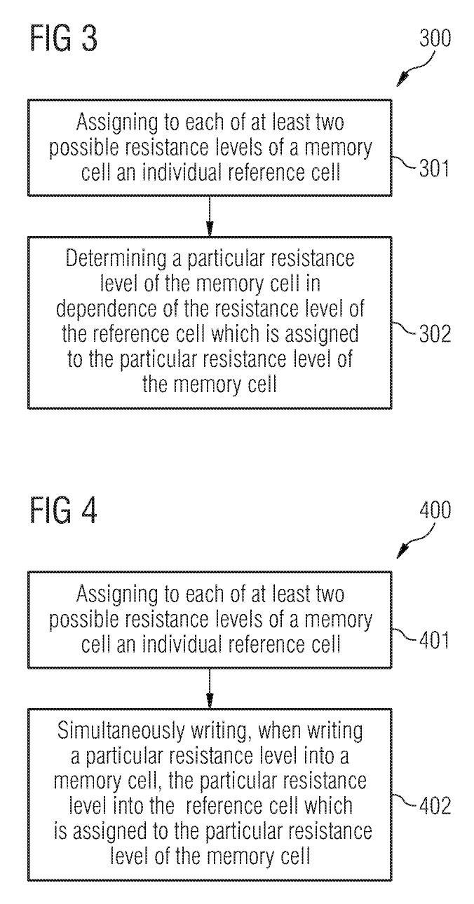

FIG. 3 shows a method 300 of operating an integrated circuit including a plurality of resistivity changing memory cells and a plurality of resistivity changing reference cells, each memory cell being switchable between N resistance levels, N being an integer greater than or equal to 2.

At 301, an individual reference cell is assigned to each of at least two possible resistance levels of a memory cell.

At 302, a particular resistance level of the memory cell is determined in dependence on the resistance level of the reference cell which is assigned to the particular resistance level of the memory cell.

According to one embodiment of the invention, the resistances of the memory cell and the reference cell are read and compared with each other, thereby determining the resistance level of the memory cell.

FIG. 4 shows a method 400 of operating an integrated circuit including a plurality of resistivity changing memory cells and a plurality of resistivity changing reference cells, each memory cell being switchable between N resistance levels, N being an integer greater than or equal to 2.

At 401, to each of at least two possible resistance levels of a memory cell, an individual reference cell is assigned.

At 402, when writing a particular resistance level into a memory cell, the particular resistance level is simultaneously written into the reference cell being assigned to the particular resistance level of the memory cell.

According to one embodiment of the invention, the following processes are carried out when writing a particular resistance level into a memory cell: determining the reference cell which has been assigned to the resistance level of the memory cell; determining all other memory cells to which the determined reference cell is also assigned, determining the memory states of the other memory cells; and rewriting the determined memory states into the other memory cells (“refreshing” the other memory cells). That is, all memory cells “belonging” to a reference cell should be refreshed when writing a particular resistance level into one memory cell “belonging” to the reference cell. According to one embodiment of the invention, the following processes are carried out when writing a particular resistance level into a memory cell: determining the reference cell which has been assigned to the resistance level of the memory cell; determining all other reference cells which are assigned to the other resistance levels of the memory cell, determining the resistance states of the other reference cells; and rewriting the determined resistance states into the other reference cells (“refreshing” the other reference cells).

An embodiment of the invention further provides a computer program product configured to perform, when being carried out on a computing device, a method of operating an integrated circuit according to embodiments of the present invention. Further, an embodiment of the invention provides a data carrier configured to store a computer program product according to an embodiment of the invention.

In the following description, making reference to FIG. 5, some basic principles underlying embodiments of the invention will be explained.

FIG. 5 shows a first actual resistance graph 501 and a second actual resistance graph 502. Further, FIG. 5 shows a first ideal resistance graph 503 and a second ideal resistance graph 504. The first actual resistance graph 501 and the first ideal resistance graph 503 start from a first resistance value 505, whereas the second actual resistance graph 502 and the second ideal resistance graph 504 start from a second resistance value 506. The first ideal resistance graph 503 represents the behavior of a first resistance level in an ideal memory cell which does not change over the time. In a similar way, the second ideal resistance graph 504 represents the behavior of a second resistance level in an ideal memory cell which does not change over the time. The first actual resistance graph 501 represents the actual behavior of a memory cell which has been programmed to the first resistance value 505 at time T0. In the same way, the second actual resistance graph 502 represents the actual behavior of a memory cell which has been programmed to the second resistance value 506 at time T0.

As can be derived from FIG. 5, the second actual resistance graph 502 intersects the first ideal resistance graph 503 at time T1. This means that, after having programmed a memory cell to the second resistance value 506 at time T0, it cannot be determined at time T1 and after time T1 whether the memory cell had been programmed to the first resistance value 505 or to the second resistance value 506 at time T0.

However, according to one embodiment of the invention, each time a memory cell is programmed to a particular resistance level, a reference cell, which is assigned to the particular resistance level of the memory cell is programmed to the same resistance level. Since the reference cell shows an identical or similar architecture as that of the memory cell, the reference cell shows the same actual resistance graph as that of the memory cell which has been programmed to the resistance level. As a consequence, by comparing the actual resistance value of the memory cell with the actual resistance value of the reference cell (the resistance values of the reference cell and the memory cell are measured simultaneously), it is possible to determine to which resistance value the memory cell has been programmed at time T0. This means that it is possible to distinguish between the first resistance value 505 and the second resistance value 506 until time T2.

According to an embodiment of the present invention, is distinguished between the first resistance value 505 and the second resistance value 506 even after time T2. In this embodiment, only a short time interval around time T2 does not allow to distinguish between the first resistance value 505 and the second resistance value 506.

According to an embodiment of the invention, at or before time T2, the resistance values of the memory cells and the reference cells are refreshed, i.e., reset to the resistance values to which they had been set at time T0.

The principle explained in conjunction with FIG. 5 can also be applied to arbitrary numbers of resistance levels (the number of resistance levels is equal to or larger than two).

According to one embodiment of the invention, an integrated circuit having a plurality of resistivity changing memory cells and a plurality of resistivity changing reference cells is provided, wherein to each possible resistance level of a memory cell an individual reference cell is assigned.

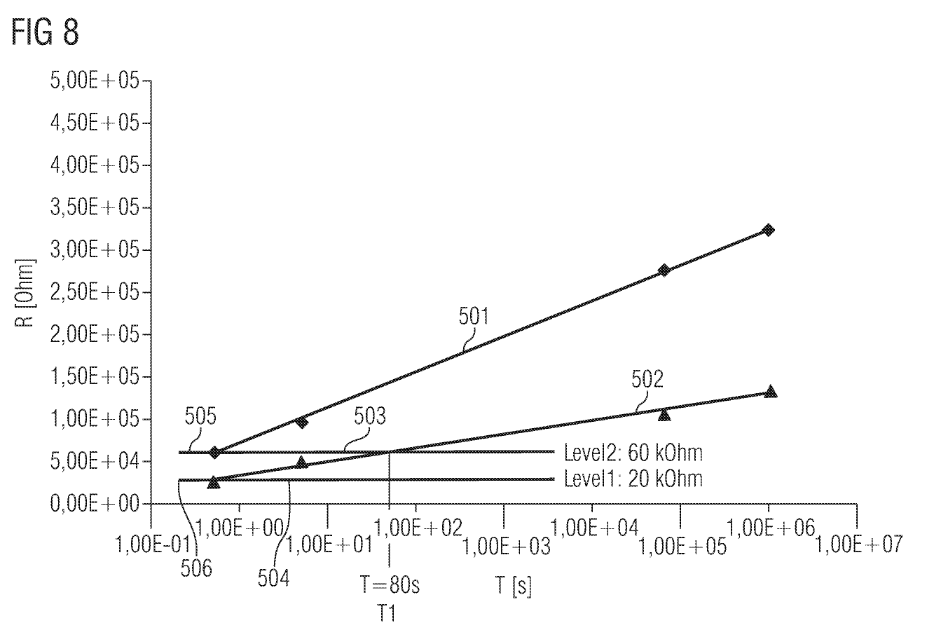

FIG. 8 illustrates the effects described in conjunction with FIG. 5 assuming that the memory cell is a solid electrolyte memory cell. As can be derived from FIG. 8, a first resistance value 505 which is about 60 kΩ cannot be distinguished from a second resistance value 506 which is about 20 kΩ after 80 seconds (T1).

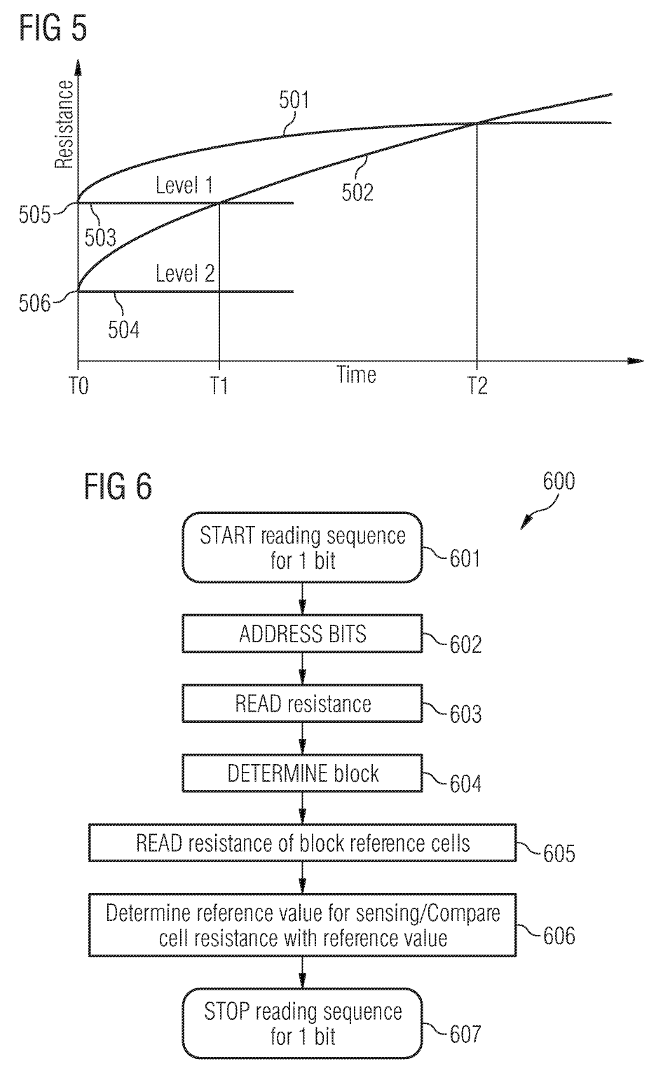

FIG. 6 shows a method 600 of operating an integrated circuit according to one embodiment of the invention. The method 600 is used in order to read the resistance value of a single memory cell of a memory device.

At 601, the method is started.

At 602, the memory cell from which data is to be read is determined.

At 603, the resistance of the memory cell determined is read.

At 604, the block of memory cells is determined which comprises the memory cell from which the resistance has been read.

At 605, the resistance values of the reference cells which are assigned to the memory cell from which data is to be read are determined. Here, all memory cells of the memory cell block determined share the same reference cells. As a consequence, after having determined the memory cell block in 604, the resistance values of the reference cells assigned to the determined memory cell block are read out.

At 606, the resistance values of the reference cells determined in 605 are compared with a resistance value read from the memory cell. The resistance level of the memory cell corresponds to the resistance level represented by the resistance value of the reference cell which comes closest to a resistance value of the memory cell. After having determined the resistance level of the memory cell, the method is terminated in a seventh process 607.

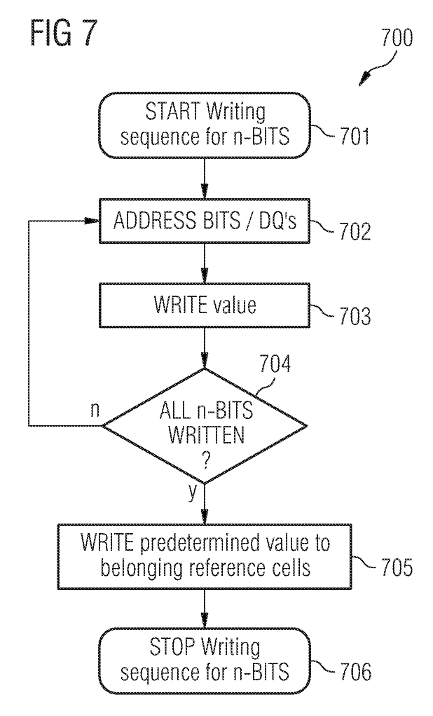

FIG. 7 shows a method 700 of operating an integrated circuit according to one embodiment of the invention. The method 700 serves for setting a plurality of memory cells (n memory cells) to particular resistance levels.

At 701, the method is started.

At 702, the memory cells are determined which are to be programmed.

At 703, the resistance value of a first memory cell is written.

At 704, it is determined whether all n memory cells have already been programmed. 702 and 703 are repeated until it is determined at 704 that all n memory cells have been programmed.

At 705, corresponding resistance values are written into the reference cells which are assigned to the memory cells.

At 706, the method 700 is terminated.

According to one embodiment of the invention, in the method shown in FIG. 7, in order to program one single memory cell, all remaining memory cells of the memory cell block (more generally: of the memory cell unit) which comprises the memory cell to be programmed are also reprogrammed. Further, when programming the memory cells of the memory cell block (more generally: of the memory cell unit), also the reference cells which are assigned to the memory cell block (more generally: of the memory cell unit) are reprogrammed. In this way, it is ensured that the “drifting behavior” of the memory cells is “synchronized” with the drifting behavior of the reference cells.

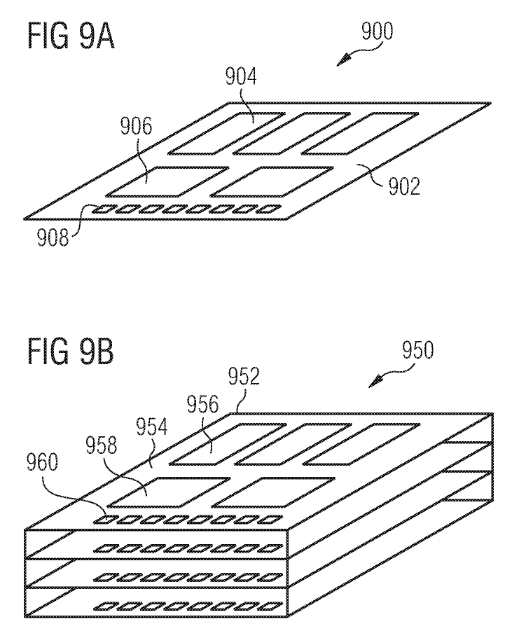

As shown in FIGS. 9A and 9B, in some embodiments, memory devices such as those described herein may be used in modules. In FIG. 9A, a memory module 900 is shown, on which one or more integrated circuits and/or memory devices and/or memory cells 904 are arranged on a substrate 902. The memory module 900 may also include one or more electronic devices 906, which may include memory, processing circuitry, control circuitry, addressing circuitry, bus interconnection circuitry, or other circuitry or electronic devices that may be combined on a module with a memory device, such as the integrated circuits and/or memory devices and/or memory cells 904. Additionally, the memory module 900 includes multiple electrical connections 908, which may be used to connect the memory module 900 to other electronic components, including other modules.

As shown in FIG. 9B, in some embodiments, these modules may be stackable, to form a stack 950. For example, a stackable memory module 952 may contain one or more memory devices 956, arranged on a stackable substrate 954. The memory device 956 contains memory cells that employ memory elements in accordance with an embodiment of the invention. The stackable memory module 952 may also include one or more electronic devices 958, which may include memory, processing circuitry, control circuitry, addressing circuitry, bus interconnection circuitry, or other circuitry or electronic devices that may be combined on a module with a memory device, such as the memory device 956. Electrical connections 960 are used to connect the stackable memory module 952 with other modules in the stack 950, or with other electronic devices. Other modules in the stack 950 may include additional stackable memory modules, similar to the stackable memory module 952 described above, or other types of stackable modules, such as stackable processing modules, control modules, communication modules, or other modules containing electronic components.

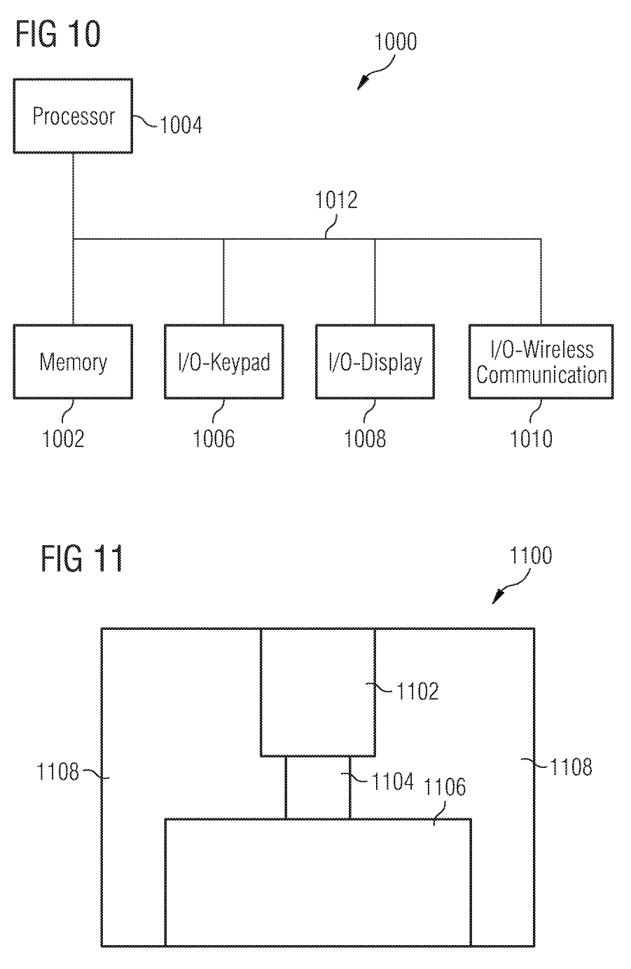

In accordance with some embodiments of the invention, integrated circuits or memory cell array as described herein may be used in a variety of applications or systems, such as the illustrative computing system shown in FIG. 10. The computing system 1000 includes an integrated circuit or memory cell array 1002. The system also includes a processing apparatus 1004, such as a microprocessor or other processing device or controller, as well as input and output apparatus, such as a keypad 1006, display 1008, and/or wireless communication apparatus 1010. The integrated circuit or memory cell array 1002, processing apparatus 1004, keypad 1006, display 1008 and wireless communication apparatus 1010 are interconnected by a bus 1012.

The wireless communication apparatus 1010 may have the ability to send and/or receive transmissions over a cellular telephone network, a WiFi wireless network, or other wireless communication network. It will be understood that the various input/output devices shown in FIG. 10 are merely examples. Memory devices including memory cells in accordance with embodiments of the invention may be used in a variety of systems. Alternative systems may include a variety of input and output devices, multiple processors or processing apparatus, alternative bus configurations, and many other configurations of a computing system. Such systems may be configured for general use, or for special purposes, such as cellular or wireless communication, photography, playing music or other digital media, or any other purpose now known or later conceived to which an electronic device or computing system including memory may be applied. The computing system may, for example, be a digital camera, a handheld, a mobile phone, a personal computer or the like.

According to one embodiment of the invention, the resistivity changing memory cells are phase changing memory cells that include a phase changing material. The phase changing material can be switched between at least two different crystallization states (i.e., the phase changing material may adopt at least two different degrees of crystallization), wherein each crystallization state may be used to represent a memory state. When the number of possible crystallization states is two, the crystallization state having a high degree of crystallization is also referred to as “crystalline state”, whereas the crystallization state having a low degree of crystallization is also referred to as “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following that the phase changing material can adopt two crystallization states (an “amorphous state” and a “crystalline state”), however it will be understood that additional intermediate states may also be used.

Phase changing memory cells may change from the amorphous state to the crystalline state (and vice versa) due to temperature changes of the phase changing material. These temperature changes may be caused using different approaches. For example, a current may be driven through the phase changing material (or a voltage may be applied across the phase changing material). Alternatively, a current or a voltage may be fed to a resistive heater which is disposed adjacent to the phase changing material. To determine the memory state of a resistivity changing memory cell, a sensing current may routed through the phase changing material (or a sensing voltage may be applied across the phase changing material), thereby sensing the resistance of the resistivity changing memory cell, which represents the memory state of the memory cell.

FIG. 11 illustrates a cross-sectional view of an exemplary phase changing memory cell 1100 (active-in-via type). The phase changing memory cell 1100 includes a first electrode 1102, a phase changing material 1104, a second electrode 1106, and an insulating material 1108. The phase changing material 1104 is laterally enclosed by the insulating material 1108. To use the phase changing memory cell in a memory cell, a selection device (not shown), such as a transistor, a diode, or another active device, may be coupled to the first electrode 1102 or to the second electrode 1106 to control the application of a current or a voltage to the phase changing material 1104 via the first electrode 1102 and/or the second electrode 1106. To set the phase changing material 1104 to the crystalline state, a current pulse and/or voltage pulse may be applied to the phase changing material 1104, wherein the pulse parameters are chosen such that the phase changing material 1104 is heated above its crystallization temperature, while keeping the temperature below the melting temperature of the phase changing material 1104. To set the phase changing material 1104 to the amorphous state, a current pulse and/or voltage pulse may be applied to the phase changing material 1104, wherein the pulse parameters are chosen such that the phase changing material 1104 is quickly heated above its melting temperature, and is quickly cooled.

The phase changing material 1104 may include a variety of materials. According to one embodiment, the phase changing material 1104 may include or consist of a chalcogenide alloy that includes one or more cells from group VI of the periodic table. According to another embodiment, the phase changing material 1104 may include or consist of a chalcogenide compound material, such as GeSbTe, SbTe, GeTe or AgInSbTe. According to a further embodiment, the phase changing material 1104 may include or consist of chalcogen free material, such as GeSb, GaSb, InSb, or GeGaInSb. According to still another embodiment, the phase changing material 1104 may include or consist of any suitable material including one or more of the cells Ge, Sb, Te, Ga, Bi, Pb, Sn, Si, P, O, As, In, Se, and S.

According to one embodiment, at least one of the first electrode 1102 and the second electrode 1106 may include or consist of Ti, V, Cr, Zr, Nb, Mo, Hf, Ta, W, or mixtures or alloys thereof. According to another embodiment, at least one of the first electrode 1102 and the second electrode 1106 may include or consist of Ti, V, Cr, Zr, Nb, Mo, Hf, Ta, W and two or more cells selected from the group consisting of B, C, N, O, Al, Si, P, S, and/or mixtures and alloys thereof. Examples of such materials include TiCN, TiAlN, TiSiN, W—Al₂O₃ and Cr—Al₂O₃.

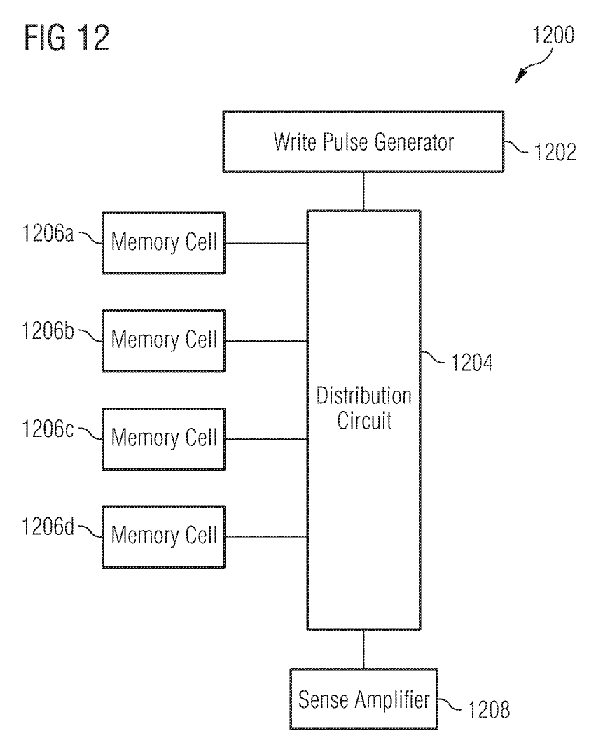

FIG. 12 illustrates a block diagram of a memory device 1200 including a write pulse generator 1202, a distribution circuit 1204, phase changing memory cells 1206a, 1206b, 1206c, 1206d (for example phase changing memory cells 1100 as shown in FIG. 11), and a sense amplifier 1208. According to one embodiment, a write pulse generator 1202 generates current pulses or voltage pulses that are supplied to the phase changing memory cells 1206a, 1206b, 1206c, 1206d via the distribution circuit 1204, thereby programming the memory states of the phase changing memory cells 1206a, 1206b, 1206c, 1206d. According to one embodiment, the distribution circuit 1204 includes a plurality of transistors that supply direct current pulses or direct voltage pulses to the phase changing memory cells 1206a, 1206b, 1206c, 1206d or to heaters being disposed adjacent to the phase changing memory cells 1206a, 1206b, 1206c, 1206d.

As already indicated, the phase changing material of the phase changing memory cells 1206a, 1206b, 1206c, 1206d may be changed from the amorphous state to the crystalline state (or vice versa) under the influence of a temperature change. More generally, the phase changing material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 1208 is capable of determining the memory state of one of the phase changing memory cells 1206a, 1206b, 1206c, or 1206d in dependence on the resistance of the phase changing material.

To achieve high memory densities, the phase changing memory cells 1206a, 1206b, 1206c, 1206d may be capable of storing multiple bits of data, i.e., the phase changing material may be programmed to more than two resistance values. For example, if a phase changing memory cell 1206a, 1206b, 1206c, 1206d is programmed to one of three possible resistance levels, 1.5 bits of data per memory cell can be stored. If the phase changing memory cell is programmed to one of four possible resistance levels, two bits of data per memory cell can be stored, and so on.

The embodiment shown in FIG. 12 may also be applied in a similar manner to other types of resistivity changing memory cells like programmable metallization cells (PMCs), magento-resistive memory cells (e.g., MRAMs) or organic memory cells (e.g., ORAMs).

Another type of resistivity changing memory cell may be formed using carbon as a resistivity changing material. Generally, amorphous carbon that is rich is sp³-hybridized carbon (i.e., tetrahedrally bonded carbon) has a high resistivity, while amorphous carbon that is rich in sp²-hybridized carbon (i.e., trigonally bonded carbon) has a low resistivity. This difference in resistivity can be used in a resistivity changing memory cell.

In one embodiment, a carbon memory cell may be formed in a manner similar to that described above with reference to phase changing memory cells. A temperature-induced change between an sp³-rich state and an sp²-rich state may be used to change the resistivity of an amorphous carbon material. These differing resistivities may be used to represent different memory states. For example, a high resistance sp³-rich state can be used to represent a “0”, and a low resistance sp²-rich state can be used to represent a “1”. It will be understood that intermediate resistance states may be used to represent multiple bits, as discussed above.

Generally, in this type of carbon memory cell, application of a first temperature causes a change of high resistivity sp³-rich amorphous carbon to relatively low resistivity sp²-rich amorphous carbon. This conversion can be reversed by application of a second temperature, which is typically higher than the first temperature. As discussed above, these temperatures may be provided, for example, by applying a current and/or voltage pulse to the carbon material. Alternatively, the temperatures can be provided by using a resistive heater that is disposed adjacent to the carbon material.

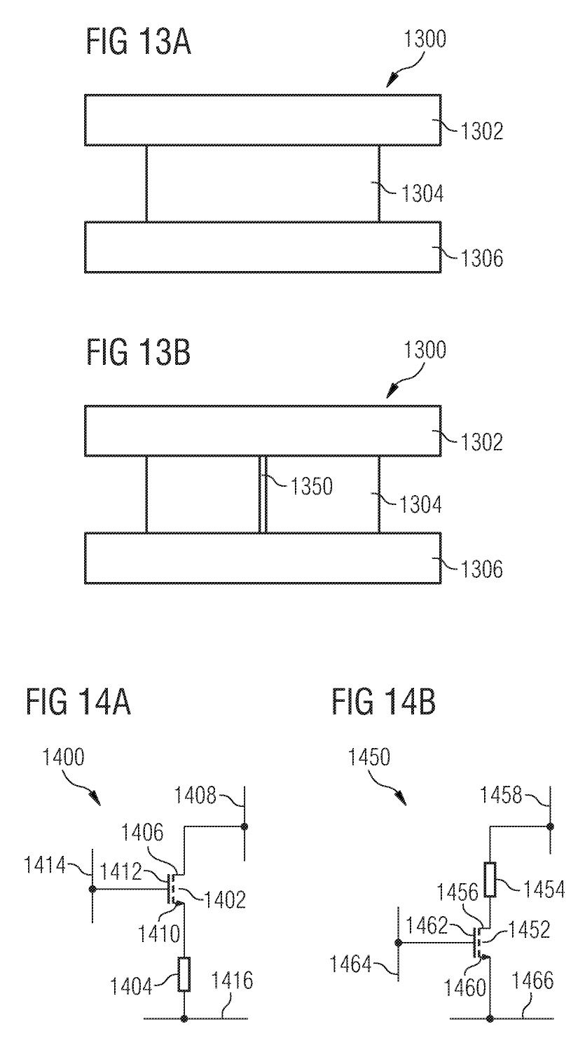

Another way in which resistivity changes in amorphous carbon can be used to store information is by field-strength induced growth of a conductive path in an insulating amorphous carbon film. For example, applying voltage or current pulses may cause the formation of a conductive sp² filament in insulating sp³-rich amorphous carbon. The operation of this type of resistive carbon memory is illustrated in FIGS. 13A and 13B.

FIG. 13A shows a carbon memory cell 1300 that includes a top contact 1302, a carbon storage layer 1304 including an insulating amorphous carbon material rich in sp³-hybridized carbon atoms, and a bottom contact 1306. As shown in FIG. 13B, by forcing a current (or voltage) through the carbon storage layer 1304, an sp² filament 1350 can be formed in the sp³-rich carbon storage layer 1304, changing the resistivity of the memory cell. Application of a current (or voltage) pulse with higher energy (or, in some embodiments, reversed polarity) may destroy the sp² filament 1350, increasing the resistance of the carbon storage layer 1304. As discussed above, these changes in the resistance of the carbon storage layer 1304 can be used to store information, with, for example, a high resistance state representing a “0” and a low resistance state representing a “1”. Additionally, in some embodiments, intermediate degrees of filament formation or formation of multiple filaments in the sp³-rich carbon film may be used to provide multiple varying resistivity levels, which may be used to represent multiple bits of information in a carbon memory cell. In some embodiments, alternating layers of sp³-rich carbon and sp²-rich carbon may be used to enhance the formation of conductive filaments through the sp³-rich layers, reducing the current and/or voltage that may be used to write a value to this type of carbon memory.

Resistivity changing memory cells, such as the phase changing memory cells and carbon memory cells described above, may include a transistor, diode, or other active component for selecting the memory cell. FIG. 14A shows a schematic representation of such a memory cell that uses a resistivity changing memory element. The memory cell 1400 includes a select transistor 1402 and a resistivity changing memory element 1404. The select transistor 1402 includes a source 1406 that is connected to a bit line 1408, a drain 1410 that is connected to the memory element 1404, and a gate 1412 that is connected to a word line 1414. The resistivity changing memory element 1404 also is connected to a common line 1416, which may be connected to ground, or to other circuitry, such as circuitry (not shown) for determining the resistance of the memory cell 1400, for use in reading. Alternatively, in some configurations, circuitry (not shown) for determining the state of the memory cell 1400 during reading may be connected to the bit line 1408. It should be noted that as used herein the terms connected and coupled are intended to include both direct and indirect connection and coupling, respectively.

To write to the memory cell 1400, the word line 1414 is used to select the memory cell 1400, and a current (or voltage) pulse on the bit line 1408 is applied to the resistivity changing memory element 1404, changing the resistance of the resistivity changing memory element 1404. Similarly, when reading the memory cell 1400, the word line 1414 is used to select the cell 1400, and the bit line 1408 is used to apply a reading voltage (or current) across the resistivity changing memory element 1404 to measure the resistance of the resistivity changing memory element 1404.

The memory cell 1400 may be referred to as a 1T1J cell, because it uses one transistor, and one memory junction (the resistivity changing memory element 1404). Typically, a memory device will include an array of many such cells. It will be understood that other configurations for a 1T1J memory cell, or configurations other than a 1T1J configuration may be used with a resistivity changing memory element. For example, in FIG. 14B, an alternative arrangement for a 1T1J memory cell 1450 is shown, in which a select transistor 1452 and a resistivity changing memory element 1454 have been repositioned with respect to the configuration shown in FIG. 14A. In this alternative configuration, the resistivity changing memory element 1454 is connected to a bit line 1458, and to a source 1456 of the select transistor 1452. A drain 1460 of the select transistor 1452 is connected to a common line 1466, which may be connected to ground, or to other circuitry (not shown), as discussed above. A gate 1462 of the select transistor 1452 is controlled by a word line 1464.

In the following description, further embodiments of the invention will be explained.

Resistive memories like CBRAM, PCRAM, or MRAM include memory elements which can adopt different electrical resistance states, respectively. In the simplest case, two resistance states can be adopted (one bit cell), also referred to as Rₒₙ state (low resistance) and as R_{off} state (high resistance). Generally, a memory cell which can adopt 2ⁿ resistance states (n bit cell) is referred to as multilevel cell (MLC). It is possible to create transitions between the different resistance states using appropriate electrical stimulations. Ideal resistive memories are non-volatile, i.e. maintain the resistance state once's programmed over a long period of time (≈10 years), even if the memory device is decoupled from an energy source.

However, the resistance levels show a drift in reality which is dependent on time and temperature, i.e. after a particular time t different resistance levels can not be distinguished from each other anymore.

Thus, several effects are the result:

a) the memory element has to be refreshed after a relatively short period of time;

b) the maximum amount of possible resistance levels is limited.

It is possible to overcome the effects mentioned above using relatively short refreshing times or limiting the maximum amount of possible resistance levels. The limitation of the maximum amount of possible resistance levels is directly coupled to the required chip area needed per bit. The use of relatively short refreshing periods limits the range of applications of the memory devices.

According to one embodiment of the invention, so called reference cells are introduced which may be from the same type as the memory cells, and which can solve this problem. The reference cells have the same characteristics as the memory cells itself. According to one embodiment of the invention, for a particular amount of memory cells of a memory device (i.e., for a memory cell unit, e.g. per block, per segment, per bank, per chip, . . . ), n reference cells are provided, for each of p different resistance levels. In the operating mode, the above mentioned memory cell unit is always reprogrammed (written or erased) in total. At the same time, the n reference cells are set to corresponding reference levels during the programming process. During the reading process of one of the memory cells of the above mentioned memory cell unit, the reference (current or voltage) is not determined in a fixed way, but using the reference cells. In an embodiment, one effect of this is that the maximum amount of possible resistance levels which can be distinguished from each other can be increased, while at the same time the retention time keeps constant. Alternatively, the retention time is maximized while keeping the amount of resistance levels constant.

A principle underlying at least one embodiment of the present invention is an operating mode of a resistive memory device, in which the memory device is divided into blocks, wherein so called reference cells are assigned to each block. Each block can only be reprogrammed (written or erased) as a whole. During a reading process, the reference is individually determined for each block using the references cells.

As used herein, the terms “connected” and “coupled” are intended to include both direct and indirect connection and coupling, respectively.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit comprising:
a plurality of resistivity changing memory cells; and
a plurality of resistivity changing reference cells;
wherein the integrated circuit being arranged such that each memory cell is switchable between N resistance levels, N being an integer greater than or equal to 2;
wherein to each of at least two possible resistance levels of a memory cell an individual reference cell is assigned; and
wherein a resistance level of a memory cell is determined or set depending on the resistance level of the reference cell that is assigned to the resistance level of the memory cell.

2. The integrated circuit according to claim 1, wherein to each possible resistance level of a memory cell an individual reference cell is assigned.

3. The integrated circuit according to claim 1, wherein the memory cells form a memory cell array.

4. The integrated circuit according to claim 3, wherein all memory cells of the memory cell array share N reference cells.

5. The integrated circuit according to claim 3, wherein the memory cell array comprises memory cell blocks such that N reference cells are assigned to each memory cell block, wherein the N reference cells that are assigned to a memory cell block are shared by the memory cells of the memory cell block.

6. The integrated circuit according to claim 3, wherein the memory cell array comprises memory cell banks such that N reference cells are assigned to each memory cell bank, wherein the N reference cells that are assigned to a memory cell bank are shared by the memory cells of the memory cell bank.

7. The integrated circuit according to claim 1, wherein the resistance levels of the memory cells are split into a first resistance level group and a second resistance level group, wherein the resistance levels of the first resistance level group are easier to distinguish from other resistance levels than the resistance levels of the second resistance level group, wherein reference cells are only assigned to resistance levels belonging to the second resistance level group.

8. The integrated circuit according to claim 1, wherein the reference cells being assigned to neighboring resistance levels are refreshed as long as the neighboring resistance levels can be distinguished from each other.

9. The integrated circuit according to claim 1, wherein only one reference cell is assigned to the highest resistance level of all memory cells.

10. The integrated circuit according to claim 1, wherein the reference cells have a density that ranges between one set of reference cells per byte and one set of reference cells per memory cell array, wherein the number of reference cells of one set of reference cells is equal to the number of possible resistance levels of one memory cell.

11. The integrated circuit according to claim 1, wherein the memory cells and the reference cells are programmable metallization cells.

12. The integrated circuit according to claim 1, wherein the memory cells and the reference cells are solid electrolyte cells.

13. The integrated circuit according to claim 1, wherein the memory cells and the reference cells are phase changing cells.

14. The integrated circuit according to claim 1, wherein the memory cells and the reference cells are carbon cells.

15. An integrated circuit comprising:
a plurality of resistivity changing memory cells; and
a plurality of resistivity changing reference cells, wherein to each possible resistance level of a memory cell an individual reference cell is assigned.

16. A memory cell array comprising:
a plurality of resistivity changing memory cells; and
a plurality of resistivity changing reference cells;
wherein each memory cell is switchable between N resistance levels, N being an integer greater than or equal to 2;
wherein to each of at least two possible resistance levels of a memory cell an individual reference cell is assigned; and
wherein the memory cell array is operable such that a resistance level of a memory cell is determined or is set depending on the resistance level of the reference cell that is assigned to the resistance level of the memory cell.

17. An integrated circuit comprising:
a plurality of resistivity changing memory means; and
a plurality of resistivity changing reference means;
wherein each memory means is switchable between N resistance levels, N being an integer greater than or equal to 2,
wherein to each of at least two possible resistance levels of a memory means an individual reference means is assigned; and
wherein a resistance level of a memory means is determined or set depending on the resistance level of the reference means which is assigned to the resistance level of the memory means.

18. A memory module comprising:
a first integrated circuit including at least one memory cell array that comprises a plurality of resistivity changing memory cells and a plurality of resistivity changing reference cells, wherein each memory cell is switchable between N resistance levels, N being an integer greater than or equal to 2, wherein to each of at least two possible resistance levels of a memory cell an individual reference cell is assigned, and wherein a resistance level of a memory cell is determined or is set depending on the resistance level of the reference cell which is assigned to the resistance level of the memory cell; and
a second integrated circuit interconnected with the first integrated circuit.

19. The memory module according to claim 18, wherein the memory module is stackable.

20. A method of operating an integrated circuit comprising a plurality of resistivity changing memory cells and a plurality of resistivity changing reference cells, each memory cell being switchable between N resistance levels, N being an integer greater than or equal to 2, the method comprising:
assigning to each of at least two possible resistance levels of a memory cell an individual reference cell; and
determining a resistance level of the memory cell depending on the resistance level of the reference cell which is assigned to the resistance level of the memory cell.

21. The method according to claim 20, wherein, in order to determine the resistance level of a memory cell, the resistances of the memory cell and the reference cell are read and compared with each other.

22. A method of operating an integrated circuit comprising a plurality of resistivity changing memory cells and a plurality of resistivity changing reference cells, each memory cell being switchable between N resistance levels, N being an integer greater than or equal to 2, the method comprising:
assigning to each of at least two possible resistance levels of a memory cell an individual reference cell; and
simultaneously writing, when writing a resistance level into the memory cell, the resistance level into the reference cell that is assigned to the resistance level of the memory cell.

23. The method according to claim 22, wherein, when writing a resistance level into a memory cell, the method comprises:
determining the reference cell which is assigned to the memory cell;
determining all other memory cells which are assigned to the determined reference cell;
determining the memory states of the other memory cells; and
rewriting the determined memory states into the other memory cells.

24. A computing system, comprising:
an input apparatus;
an output apparatus;
a processing apparatus; and
a memory comprising a plurality of resistivity changing memory cells and a plurality of resistivity changing reference cells, each memory cell being switchable between N resistance levels, N being an integer greater than or equal to 2, the memory being arranged such that each memory cell is switchable between N resistance levels, N being an integer greater than or equal to 2, wherein to each of at least two possible resistance levels of a memory cell an individual reference cell is assigned, and wherein a resistance level of a memory cell is determined or set depending on the resistance level of the reference cell that is assigned to the resistance level of the memory cell.

25. The computing system according to claim 24, wherein the computing system comprises a personal computer, a mobile phone, a handheld, or a digital camera.
